(19) United States
(12) Patent Application Publication
(10) Pub. No.: US 2014/0311558 A1
(43) Pub. Date: Oct. 23, 2014

(54) SOLAR CELL AND METHOD FOR MANUFACTURING THE SAME

(71) Applicant: LG ELECTRONICS INC., Seoul (KR)

(72) Inventors: Seungjik LEE, Seoul (KR); Sehwon AHN, Seoul (KR)

(73) Assignee: LG ELECTRONICS INC., Seoul (KR)

(21) Appl. No.: 14/243,560

(22) Filed: Apr. 2, 2014

(30) Foreign Application Priority Data
Apr. 18, 2013 (KR) 10-2013-0042756

(51) Int. Cl. H01L 31/068; H01L 31/18

(52) U.S. Cl. CPC H01L 31/0682; H01L 31/1864
USPC 136/255; 438/98

(57) ABSTRACT

A solar cell includes a semiconductor substrate containing impurities of a first conductive type, a back surface field region which is positioned on a back surface of the semiconductor substrate and is doped more than the semiconductor substrate with impurities of the first conductive type, an emitter region which is on the back surface of the semiconductor substrate adjacent to the back surface field region and contains impurities of a second conductive type different than the first conductive type, a metal layer which contains impurities of the second conductive type and on a back surface of the emitter region, a back passivation layer exposing a portion of the back surface field region and a portion of the metal layer.

This application claims priority to and the benefit of Korean Patent Application No. 10-2013-0042756 filed in the Korean Intellectual Property Office on Apr. 18, 2013, the entire contents of which are incorporated by reference as if fully set forth herein.

### BACKGROUND

1. Field of the Disclosure

Embodiments of the invention relate to a solar cell and a method for manufacturing the same.

2. Description of the Related Art

Recently, as existing energy sources such as petroleum and coal are expected to be depleted, interests in alternative energy sources for replacing the existing energy sources are increasing. Among the alternative energy sources, solar cells for generating electric energy from solar energy have been particularly spotlighted.

A silicon solar cell generally includes a substrate and an emitter region, which are formed of semiconductors of different conductive types, for example, a p-type and an n-type, and electrodes respectively connected to the substrate and the emitter region. A p-n junction is formed at an interface between the substrate and the emitter region.

When light is incident on the solar cell, a plurality of electron-hole pairs are generated in the semiconductors. The electron-hole pairs are separated into electrons and holes by a photovoltaic effect. The electrons move to the n-type semiconductor, for example, the emitter region, and the holes move to the p-type semiconductor, for example, the substrate. Then, the electrons and the holes are collected by the electrodes electrically connected to the emitter region and the substrate. The electrodes are connected to each other using electric wires to thereby conduct electric power.

However, in some cases, the electrodes are positioned on the emitter region formed at the surface (i.e., an incident surface) of the substrate, on which light is incident, as well as the surface of the substrate, on which light is not incident. Therefore, an area of incident light decreases, and the efficiency of the solar cell is reduced.

Accordingly, a back contact solar cell, in which all of the electrodes collecting the electrons and the holes are positioned on the back surface of the substrate, has been developed, so as to increase the area of incident light.

### SUMMARY

Embodiments of the invention provide a solar cell, which is able to be manufactured at a low price, and a method for manufacturing the same.

In one aspect, there is a solar cell including a semiconductor substrate containing impurities of a first conductive type, a back surface field region which is positioned on a back surface of the semiconductor substrate and is doped more than the semiconductor substrate with impurities of the first conductive type, an emitter region positioned on the back surface of the semiconductor substrate at a position adjacent to the back surface field region, the emitter region containing impurities of a second conductive type different than the first conductive type, a metal layer which contains impurities of the second conductive type and is positioned on a back surface of the emitter region, a back passivation layer exposing a portion of the back surface field region and a portion of the metal layer, a first electrode electrically connected to the back surface field region exposed by the back passivation layer, and a second electrode electrically connected to the metal layer exposed by the back passivation layer.

The solar cell may further include an impurity layer which contains impurities of the first conductive type and is positioned between the back surface field region and the back passivation layer.

The first electrode directly contacts the back surface field region, and the second electrode directly contacts the metal layer.

Because the emitter region is formed by diffusing the impurities of the second conductive type contained in the metal layer into the back surface of the semiconductor substrate, a width of the emitter region may be substantially equal to or greater than a width of the metal layer.

When the semiconductor substrate and the back surface field region are of an n-type and the emitter region is of a p-type, the metal layer may include aluminum.

The back passivation layer may contain at least one of oxide, nitride, and oxynitride.

For example, the back passivation layer may include an aluminum oxide layer positioned on a back surface of the metal layer and a silicon oxide layer positioned on a remaining area excluding a formation area of the metal layer from the back surface of the semiconductor substrate. The back surface field region may be separated from the emitter region in a vertical direction from the back surface of the semiconductor substrate or the vertical direction and a horizontal direction.

The solar cell may further include a front surface field region which is positioned on a front surface of the semiconductor substrate and is doped more than the semiconductor substrate with impurities of the first conductive type.

A distance between the front surface field region and the emitter region may be greater than a distance between the front surface field region and the back surface field region.

An impurity layer containing impurities of the first conductive type may be positioned on a front surface of the front surface field region, and an anti-reflection layer may be positioned on a front surface of the impurity layer. Further, the anti-reflection layer and the back passivation layer may include the same material or different materials.

In another aspect, there is a method for manufacturing a solar cell including a substrate providing step for providing a semiconductor substrate containing impurities of a first conductive type, a metal layer forming step for forming a metal layer containing impurities of a second conductive type different than the first conductive type on a back surface of the semiconductor substrate to expose a portion of the back surface of the semiconductor substrate, an etching step for etching the exposed portion of the back surface of the semiconductor substrate by a predetermined depth, an impurity layer forming step for forming an impurity layer containing impurities of the first conductive type on the etched portion of the back surface of the semiconductor substrate, a dielectric layer forming step for forming a dielectric layer on the entire back surface of the semiconductor substrate, and a thermal process step for performing a thermal process to diffuse the impurities of the first conductive type contained in the impurity layer and the impurities of the second conductive type contained in the metal layer into the back surface of the semiconductor substrate by a predetermined depth and simultaneously form a back surface field region and an emitter region.

In the impurity layer forming step, the impurity layer may be further formed on a surface of the semiconductor substrate.

In the dielectric layer forming step, the dielectric layer may be further formed on a surface of the impurity layer formed at the front surface of the semiconductor substrate.

In the thermal process step, the impurities of the first conductive type contained in the impurity layer formed on a front surface of the semiconductor substrate may be diffused into the front surface of the semiconductor substrate to form a front surface field region, the thermal process may be performed on the dielectric layer formed on a front surface of the front surface field region to form an anti-reflection layer, and the thermal process may be performed on the dielectric layer formed on the back surface of the semiconductor substrate to form a back passivation layer.

The method may further include an etching step for removing a portion of the back passivation layer to expose a portion of the back surface field region and a portion of the metal layer and an electrode forming step for forming a first electrode connected to the exposed portion of the back surface field region and a second electrode connected to the exposed portion of the metal layer.

In the metal layer forming step, the metal layer may be formed using a deposition method. In the etching step, the metal layer may be used as a mask.

In yet another aspect, there is a method for manufacturing a solar cell including a substrate providing step for providing a semiconductor substrate containing impurities of a first conductive type, a metal layer forming step for forming a metal layer containing impurities of a second conductive type different than the first conductive type on a back surface of the semiconductor substrate to expose a portion of the back surface of the semiconductor substrate, an etching step for etching the exposed portion of the back surface of the semiconductor substrate by a predetermined depth, an impurity layer forming step for forming an impurity layer containing impurities of the first conductive type on the etched portion of the back surface of the semiconductor substrate, a thermal process step for performing a thermal process to form a back passivation layer as a thermal oxide layer on the back surface of the semiconductor substrate and diffusing the impurities of the first conductive type contained in the impurity layer and the impurities of the second conductive type contained in the metal layer into the back surface of the semiconductor substrate by a predetermined depth to simultaneously form a back surface field region and an emitter region, an etching step for removing a portion of the back passivation layer to expose a portion of the back surface field region and a portion of the metal layer, and an electrode forming step for forming a first electrode connected to the exposed portion of the back surface field region and a second electrode connected to the exposed portion of the metal layer.

In the impurity layer forming step, the impurity layer may be further formed on a front surface of the semiconductor substrate. In the thermal process step, the thermal oxide layer may be further formed on a front surface of the impurity layer formed on the front surface of the semiconductor substrate.

In the thermal process step, the impurities of the first conductive type contained in the impurity layer formed on the front surface of the semiconductor substrate may be diffused into the front surface of the semiconductor substrate to form a front surface field region.

In the metal layer forming step, the metal layer may be formed using a deposition method. In the etching step, the metal layer may be used as a mask.

According to the above-described characteristics of the embodiments of the invention, the impurity diffusion process for forming the emitter region and the impurity diffusion process for forming the back surface field region may be simultaneously performed, and also the anti-reflection layer and the back passivation layer may be simultaneously formed in the impurity diffusion process.

Accordingly, because the number of manufacturing processes of the solar cell may be greatly reduced, the manufacturing cost of the solar cell may be reduced.

### BRIEF DESCRIPTION OF THE DRAWINGS

The accompanying drawings, which are included to provide a further understanding of the disclosure and are incorporated in and constitute a part of this specification, illustrate embodiments of the invention and together with the description serve to explain the principles of the invention. In the drawings:

FIG. 1 is a cross-sectional view schematically showing a partial structure of a solar cell according to a first exemplary embodiment of the invention;

FIG. 2 is an enlarged view of a main part of the solar cell shown in FIG. 1;

FIG. 3 is an enlarged view of a main part of a solar cell according to a modified embodiment of the invention;

FIG. 4 is a process block diagram showing a method for manufacturing the solar cell shown in FIGS. 1 and 2 according to an exemplary embodiment;

FIG. 5 sequentially illustrates a method for manufacturing the solar cell shown in FIG. 4 according to an exemplary embodiment;

FIG. 6 is a cross-sectional view schematically showing a partial structure of a solar cell according to a second exemplary embodiment of the invention;

FIG. 7 is a process block diagram showing a method for manufacturing the solar cell shown in FIG. 6 according to an exemplary embodiment; and

FIG. 8 sequentially illustrates a method for manufacturing the solar cell shown in FIG. 7.

### DETAILED DESCRIPTION OF THE EMBODIMENTS

Reference will now be made to detail embodiments of the invention examples of which are illustrated in the accompanying drawings. Since the present embodiments may be modified in various ways and may have various forms, specific embodiments are illustrated in the drawings and are described in detail in the present specification. However, it should be understood that the present embodiments are not limited to specific disclosed embodiments, but include all modifications, equivalents and substitutes included within the spirit and technical scope of the present disclosure.

The terms ‘first’, ‘second’, etc. may be used to describe various components, but the components are not limited by such terms. The terms are used only for the purpose of distinguishing one component from other components.

For example, a first component may be designated as a second component without departing from the scope of the present embodiments. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no component exists between them.

The terms used in the present application are used to describe only specific embodiments or examples, and are not intended to limit the present disclosure. A singular expression can include a plural expression as long as it does not have an apparently different meaning in context.

In the present application, the terms “include” and “have” should be understood to be intended to designate that illustrated features, numbers, steps, operations, components, parts or combinations thereof exist and not to preclude the existence of one or more different features, numbers, steps, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the present disclosure pertains.

The terms defined in a generally used dictionary may be understood to have meanings identical to those used in the context of a related art, and are not to be construed to have ideal or excessively formal meanings unless they are obviously specified in the present application.

The following exemplary embodiments of the invention are provided to those skilled in the art in order to describe the present disclosure more completely. Accordingly, shapes and sizes of elements shown in the drawings may be exaggerated for clarity.

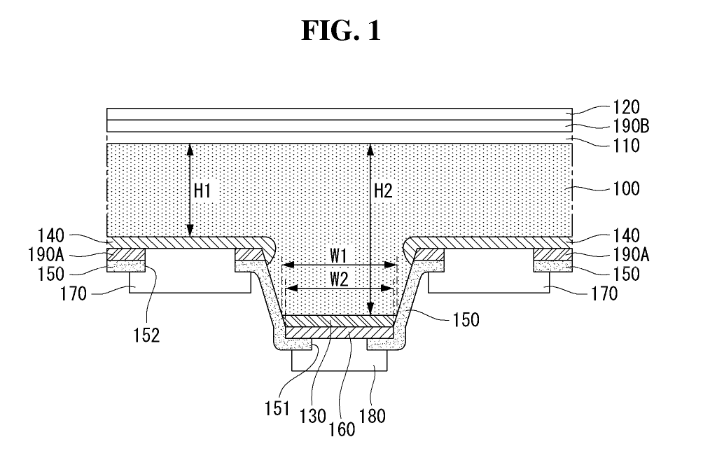

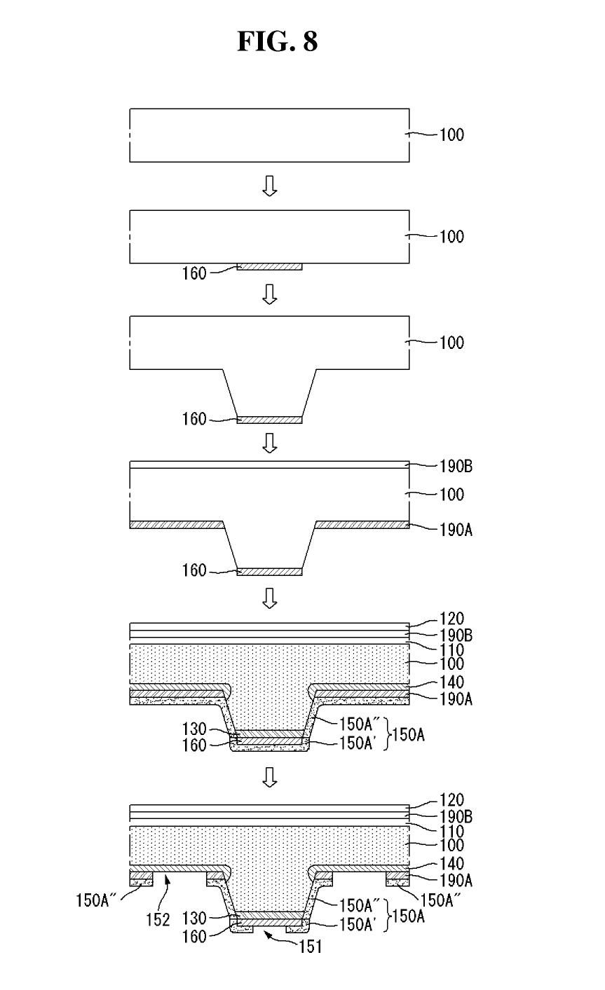

Exemplary embodiments of the invention will be described with reference to FIGS. 1 to 8.

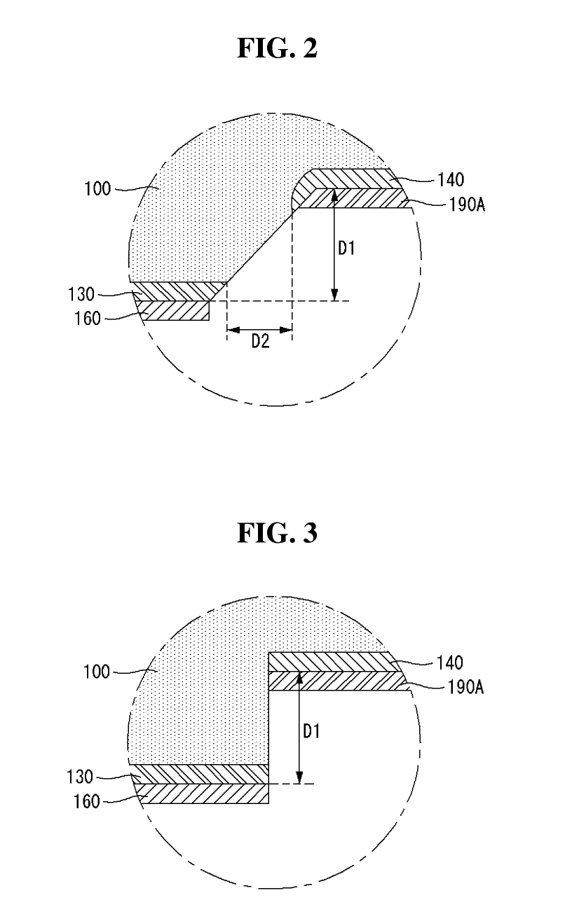

FIG. 1 is a cross-sectional view schematically showing a partial structure of a solar cell according to a first embodiment of the invention. FIG. 2 is an enlarged view of a main part of the solar cell shown in FIG. 1. FIG. 3 is an enlarged view of a main part of a solar cell according to a modified embodiment of the invention.

As shown in FIGS. 1 to 3, the solar cell according to the first embodiment of the invention includes a substrate 100, a front surface field region 110 entirely positioned at a first surface (hereinafter, referred to as “a front surface”) of the substrate 100 on which light is incident, an anti-reflection layer 120 positioned on an entire front surface of the front surface field region 110, a plurality of emitter regions 130, a plurality of back surface field regions 140 positioned at a second surface (hereinafter, referred to as “a back surface”) opposite the front surface of the substrate 100, a back passivation layer 150 positioned on back surfaces of the plurality of emitter regions 130 and back surfaces of the plurality of back surface field regions 140, a metal layer 160 positioned between the back passivation layer 150 and the emitter regions 130, a plurality of first electrodes 170 electrically connected to the back surface field regions 140, a plurality of second electrodes 180 electrically connected to the metal layer 160, an impurity layer 190A positioned between the back surface field regions 140 and the back passivation layer 150, and an impurity layer 190B positioned between the front surface field region 110 and the anti-reflection layer 120.

The substrate 100 is a semiconductor substrate formed of silicon of a first conductive type, on which impurities of the first conductive type are doped. In this instance, if the first conductive type is an n-type, the substrate 100 may contain impurities of a group V element such as phosphorus (P), arsenic (As), and antimony (Sb).

Silicon used in the substrate 100 may be crystalline silicon, such as single crystal silicon and polycrystalline silicon, or amorphous silicon.

On the contrary, the substrate 100 may be of a p-type. In this instance, the substrate 100 may contain impurities of a group III element such as boron (B), gallium (Ga), and indium (In). In another embodiment, the substrate 100 may be formed of semiconductor materials other than silicon.

The front surface of the substrate 100 may be textured to form a textured or uneven surface including a plurality of uneven portions or having uneven characteristics. Hence, an amount of specular reflected light from the front surface of the substrate 100 decreases. Further, because a plurality of incident operations and reflection operations of light are performed on the textured surface of the substrate 100, an amount of light absorbed in the substrate 100 increases. Hence, the efficiency of the solar cell is improved.

The plurality of emitter regions 130 and the plurality of back surface field regions 140 may be alternately positioned at the back surface of the substrate 100. The emitter regions 130 and the back surface field regions 140 may be separated from one another and extend in parallel with one another.

Each emitter region 130 may be an impurity region which is heavily doped with impurities of a second conductive type (for example, a p-type) different than the first conductive type of the substrate 100. The emitter region 130 may form a p-n junction along with the substrate 100.

The metal layer 160 positioned between the emitter region 130 and the back passivation layer 150 directly contacts the back surface of the emitter region 130 and is formed of a metal material, for example, aluminum (Al) containing the same conductive type of impurities contained in the emitter region 130. When an impurity diffusion process for forming the emitter region 130 and the back surface field region 140 is performed, the emitter region 130 is formed by diffusing impurities contained in the metal layer 160 into the back surface of the substrate 100.

Accordingly, a width W1 of the emitter region 130 may be substantially equal to a width W2 of the metal layer 160. Alternatively, the width W1 of the emitter region 130 may be greater than the width W2 of the metal layer 160.

Each back surface field region 140 may be an impurity region (for example, an n⁺-type region) which is more heavily doped than the substrate 100 with impurities of the same conductive type (for example, n-type) as the substrate 100. A potential barrier may be formed by a difference between impurity concentrations of the substrate 100 and the back surface field regions 140, thereby preventing or reducing holes from moving to the first electrodes 170. Thus, the back surface field regions 140 may prevent or reduce a recombination and/or a disappearance of electrons and holes at and around the first electrodes 170.

The impurity layer 190A positioned between the back surface field region 140 and the back passivation layer 150 directly contacts the back surface of the back surface field region 140 and contains the n-type impurities contained in the back surface field region 140. For example, the impurity layer 190A may be a phosphorous silicate glass (PSG) layer.

When the impurity diffusion process for forming the emitter region 130 and the back surface field region 140 is performed, the back surface field region 140 is formed by diffusing impurities contained in the impurity layer 190A into the back surface of the substrate 100.

As shown in FIG. 2, the emitter region 130 and the back surface field region 140 positioned at the back surface of the substrate 100 are separated from each other by a first distance D1 in a vertical direction, i.e., a thickness direction of the substrate 100, and also are separated from each other by a second distance D2 in a horizontal direction perpendicular to the vertical direction.

The first distance D1 refers to a shortest distance between the back surface of the emitter region 130 and the back surface of the back surface field region 140 measured in the vertical direction.

As described above, in the embodiment of the invention, because the emitter region 130 and the back surface field region 140 are separated from each other by the first distance D1 in the vertical direction and also are separated from each other by the second distance D2 in the horizontal direction, the generation of a butting phenomenon is efficiently prevented.

In general, when the emitter region 130 corresponding to a p⁺-type layer and the back surface field region 140 corresponding to an n⁺-type layer substantially contact each other or are separated from each other by a very narrow distance, the butting phenomenon, in which a current flows between the emitter region 130 and the back surface field region 140, is generated.

When the butting phenomenon is generated, an amount of electrons and holes collected by the first electrodes 170 and the second electrodes 180 decreases. As a result, photoelectric conversion efficiency is reduced, and the efficiency of the solar cell is reduced.

However, as shown in FIG. 2, when the emitter region 130 and the back surface field region 140 are separated from each other by the first distance D1 in the vertical direction and also are separated from each other by the second distance D2 in the horizontal direction, the generation of the butting phenomenon is efficiently prevented. Hence, the efficiency of the solar cell is improved.

In this instance, it is preferable, but not required, that the first distance D1 in the vertical direction is greater than the second distance D2 in the horizontal direction, so as to efficiently prevent the butting phenomenon while preventing an excessive increase in the size and the thickness of the substrate 100.

When the emitter region 130 is the p-type doped region and the back surface field region 140 is the n-type doped region, the back surface of the emitter region 130 is disposed at a position lower than the back surface of the back surface field region 140 in a state where the emitter region 130 and the back surface field region 140 are separated from each other in the vertical direction and the horizontal direction, so as to easily perform the manufacturing process.

Accordingly, as shown in FIG. 1, a first height H1 between a back surface of the front surface field region 110 and a front surface of the back surface field region 140 is less than a second height H2 between the back surface of the front surface field region 110 and a front surface of the emitter region 130, and a difference between the first height H1 and the second height H2 is substantially equal to the first distance D1.

Unlike the configuration shown in FIG. 2, the emitter region 130 and the back surface field region 140 may be separated from each other only in the vertical direction.

More specifically, as shown in FIG. 3, the emitter region 130 and the back surface field region 140 are separated from each other by the first distance D1 in the vertical direction and are not separated from each other in the horizontal direction

Even if the emitter region 130 and the back surface field region 140 are separated from each other only in the vertical direction as described above, the generation of the butting phenomenon may be prevented.

As shown in FIG. 2, the back surface of the substrate 100 between the emitter region 130 and the back surface field region 140 may be formed as an inclined surface which connects the emitter region 130 and the back surface field region 140 at a predetermined slope angle.

In this instance, the slope angle of the inclined surface may be non-uniform. In the embodiment disclosed herein, the fact that the slope angle of the inclined surface is non-uniform means that a slope angle at the emitter region 130 is different from a slope angle at the back surface field region 140.

As described above, when the back surface of the substrate 100 between the emitter region 130 and the back surface field region 140 is formed as the inclined surface which connects the emitter region 130 and the back surface field region 140 at a predetermined slope angle (i.e., when the emitter region 130 and the back surface field region 140 are separated from each other in the horizontal direction as well as the vertical direction), a width W1 of the emitter region 130 may be greater than a width W2 of the metal layer 160.

However, as shown in FIG. 3, when the emitter region 130 and the back surface field region 140 are separated from each other only in the vertical direction, the width W1 of the emitter region 130 may be substantially equal to the width W2 of the metal layer 160.

If the substrate 100 and the back surface field region 140 are of the second conductive type (for example, the p-type) unlike the embodiment described above, the emitter region 130 may be of the first conductive type (for example, the n-type) because the substrate 100 and the emitter region 130 form the p-n junction. Further, the metal layer 160 may contain impurities of the first conductive type. In this instance, the electrons move to the emitter region 130, and the holes move to the back surface field region 140.

The back passivation layer 150 positioned on the back surfaces of the plurality of emitter regions 130 and the back surfaces of the plurality of back surface field regions 140 has openings 151 and 152 [IT IS RECOMMENDED THAT THESE REFERENCES NUMERALS SHOULD BE ADDED TO FIG. 1] exposing a portion of the metal layer 160 and a portion of each back surface field region 140 and is positioned on the back surface of the substrate 100 between the metal layer 160 and the back surface field regions 140.

In this instance, the openings 151 are formed only in the back passivation layer 150, but the openings 152 are formed in the back passivation layer 150 and the impurity layer 190A. On the contrary, the openings 151 may be formed in the back passivation layer 150 and the metal layer 160.

The back passivation layer 150 protects the emitter regions 130, the back surface field regions 140, and the substrate 100. Further, the back passivation layer 150 converts a defect, for example, dangling bonds existing at and around the surface of the substrate 100 into stable bonds, thereby preventing or reducing a recombination and/or a disappearance of carriers moving to the back surface of the substrate 100.

Further, the back passivation layer 150 reflects light passing through the substrate 100 back into the substrate 100, thereby reducing a loss of incident light.

In the embodiment of the invention, the back passivation layer 150 may be formed of at least one of oxide, nitride, and oxynitride and may have a single-layered structure or a multi-layered structure.

For example, the back passivation layer 150 may be formed at a low temperature of about 200° C. to 500° C. using a chemical vapor deposition (CVD) equipment such as a plasma enhanced CVD (PECVD) equipment, a low pressure CVD (LPCVD) equipment, and an atmospheric pressure CVD (APCVD) equipment, or may be formed at a temperature of a room temperature to about 120° C. through a wet process.

The plurality of first electrodes 170 are positioned on the back surfaces of the back surface field regions 140 exposed through the openings 152 and the back surface of the back passivation layer 150 adjacent to the openings 152. The plurality of second electrodes 180 are positioned on the back surface of the metal layer 160 exposed through the openings 151 and the back surface of the back passivation layer 150 adjacent to the openings 151.

The first electrodes 170 and the second electrodes 180 are electrically separated from each other by the back passivation layer 150.

The first electrodes 170 extend nearly parallel and are electrically and physically connected to the back surface field regions 140. The first electrodes 170 collect carriers (for example, electrons) moving to the back surface field regions 140.

The second electrodes 180 are separated from the first electrodes 170, extend nearly parallel with the first electrodes 170, and are electrically and physically connected to the metal layer 160.

Because the metal layer 160 directly contacts the emitter region 130 at the back surface of the emitter region 130, the second electrode 180 is electrically connected to the emitter region 130 through the metal layer 160. Further, the metal layer 160 collects carriers (for example, holes) moving to the emitter regions 130.

As described above, the first electrode 170 and the second electrode 180 partially overlap the back passivation layer 150 and include an end portion having a wide area. Therefore, when the first electrode 170 and the second electrode 180 are connected to an external driving circuit, contact resistance decreases and contact efficiency is improved.

The front surface field region 110 positioned at the entire front surface of the substrate 100 may be an impurity region which is more heavily doped than the substrate 100 with impurities of the first conductive type. The front surface field region 110 performs the same operation as the back surface field region 140 and may be omitted if necessary or desired.

The impurity layer 190B positioned at the entire front surface of the front surface field region 110 contains impurities (for example, impurities of the first conductive type) for forming the front surface field region 110. For example, the impurity layer 190B may be formed of the same material (for example, phosphorous silicate glass (PSG)) as the impurity layer 190A.

The anti-reflection layer 120 may be positioned at the entire front surface of the impurity layer 190B may contain at least one of oxide, nitride, and oxynitride and may be formed of the same material as the back passivation layer 150.

The anti-reflection layer 120 reduces reflectance of light incident on the solar cell and increases transmission of light of a predetermined wavelength band, thereby increasing the efficiency of the solar cell. In the embodiment disclosed herein, the anti-reflection layer 120 has a single-layered structure, but may have a multi-layered structure, for example, a double-layered structure. The anti-reflection layer 120 may be omitted, if desired.

When the anti-reflection layer 120 has the multi-layered structure, the back passivation layer 150 may have a multi-layered structure in the same manner as the anti-reflection layer 120. Preferably, the anti-reflection layer 120 and the back passivation layer 150 may have the same structure.

The solar cell according to the embodiment of the invention having the above-described structure is a back contact solar cell, in which the emitter regions 130 and the back surface field regions 140 as well as the first electrodes 170 and the second electrodes 180 are positioned at the back surface of the substrate 100, on which light is not incident. An operation of the back contact solar cell according to the embodiment of the invention is described below.

When light irradiated to the front surface of the solar cell is incident on the substrate 100 through the anti-reflection layer 120 and the front surface field region 110, a plurality of electron-hole pairs are generated in the substrate 100 by light energy produced based on the incident light.

In this instance, because the front surface of the substrate 100 is formed as a textured surface, light reflectance at the front surface of the substrate 100 is reduced and an absorptance of light increases. Hence, the efficiency of the solar cell is improved.

In addition, because the anti-reflection layer 120 reduces a reflection loss of the light incident on the substrate 100, an amount of light incident on the substrate 100 further increases.

The electron-hole pairs are separated from each other due to the p-n junction of the substrate 100 and the emitter regions 130. The electrons move to the n-type semiconductor part (for example, the back surface field regions 140) and then are collected by the first electrodes 170, and the holes move to the p-type semiconductor part (for example, the emitter regions 130) and then are collected by the second electrodes 180 through the metal layer 160.

When the first electrodes 170 and the second electrodes 180 of one solar cell are connected to the second electrodes 180 and the first electrodes 170 of another solar cell adjacent to the one solar cell using electric wires, electric current flows therein to use for electric power.

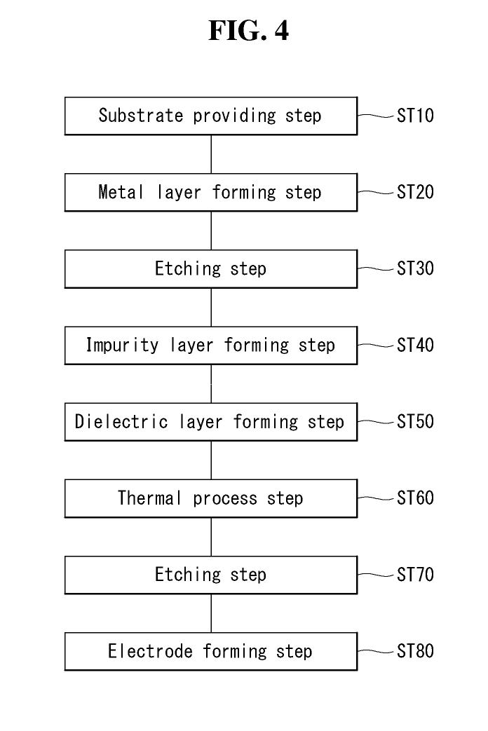

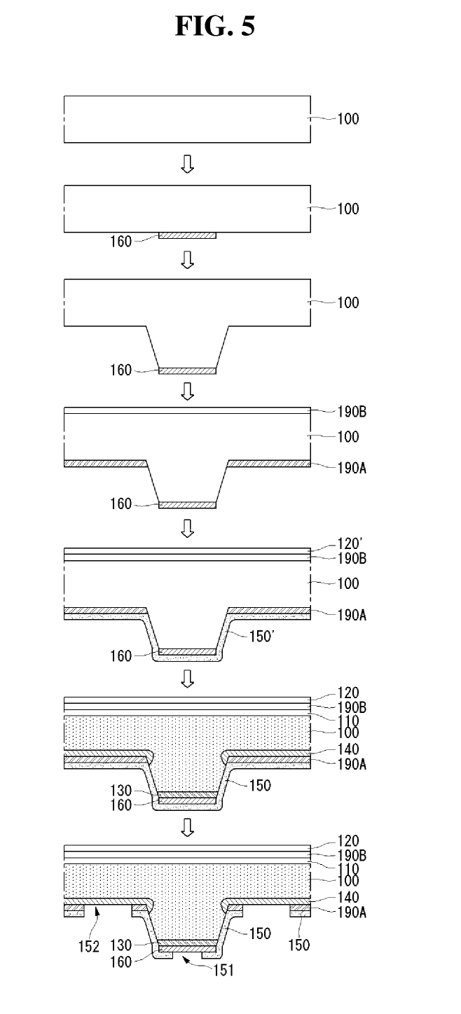

A method for manufacturing the back contact solar cell shown in FIGS. 1 and 2 is described below with reference to FIGS. 4 and 5.

FIG. 4 is a process block diagram showing a method for manufacturing the solar cell shown in FIGS. 1 and 2. FIG. 5 sequentially illustrates the manufacturing a solar cell shown in the method of FIG. 4.

The method for manufacturing the solar cell according to the first embodiment of the invention may include a substrate providing step ST10 for providing the substrate 100 containing impurities of the first conductive type; a metal layer forming step ST20 for forming the metal layer 160 containing impurities of the second conductive type different than the first conductive type on the back surface of the substrate 100 to expose a portion of the back surface of the substrate 100; an etching step ST30 for etching the exposed portion of the back surface of the substrate 100 by a predetermined depth; an impurity layer forming step ST40 for forming the impurity layer 190A containing impurities of the first conductive type at the etched portion of the back surface of the substrate 100; a dielectric layer forming step ST50 for forming a dielectric layer 150′ on the entire back surface of the substrate 100; and a thermal process step ST60 for performing a thermal process to diffuse the impurities of the first conductive type contained in the impurity layer 190A and the impurities of the second conductive type contained in the metal layer 160 into the back surface of the substrate 100 by a predetermined depth while simultaneously forming the back surface field regions 140 and the emitter regions 130.

In the substrate providing step ST10, the substrate 100 formed of silicon is generally manufactured by slicing a silicon block or an ingot using a blade or a multi-wire saw. When the silicon block or the ingot is sliced, a mechanical damage layer is formed in the substrate 100.

Accordingly, before forming the textured surface of the substrate 100, a wet etching process, a dry etching process, or other process may be performed to remove the mechanical damage layer, so as to prevent a reduction in characteristics of the solar cell resulting from the mechanical damage layer of the substrate 100.

An alkaline etchant or an acid etchant may be used in the wet etching process, and a reactive ion etching (RIE) process may be used in the dry etching process.

After removing the mechanical damage layer, one surface, for example, the front surface of the substrate 100 is processed to form the textured surface corresponding to an uneven surface including a plurality of uneven portions or having uneven characteristics.

FIG. 1 shows the front surface of the substrate 100 as substantially flat. However, the front surface of the substrate 100 may be formed as the textured surface, so as to increase incident light efficiency.

The substrate 100 may be a silicon substrate containing impurities (for example, n-type impurities) of the first conductive type.

Next, the metal layer forming step ST20 is performed to form the metal layer 160 exposing a portion of the back surface of the substrate 100 on the back surface of the substrate 100.

The metal layer 160 may be formed by depositing aluminum (Al) containing impurities of the second conductive type on the back surface of the substrate 100. A sputtering method or a vapor evaporation method may be used to as a deposition method for depositing aluminum (Al).

As shown in FIG. 5, when a shadow mask is used in the deposition method for forming the metal layer 160, the metal layer 160 exposing a portion of the back surface of the substrate 100 may be formed without a separate patterning process.

Next, the etching step ST30 is performed. In the etching step ST30, the exposed portion of the back surface of the substrate 100 is etched by a predetermined depth using the metal layer 160 as a mask.

After the etching step is completed, the impurity layer forming step ST40 is performed to form the impurity layer 190A at the etched portion of the back surface of the substrate 100. In this instance, it is preferable, but not required, that the impurity layer 190B is formed on the entire front surface of the substrate 100. Further, it is preferable, but not required, that the impurity layers 190A and 190B are simultaneously formed.

The impurity layer 190B contains impurities used to form the front surface field region 110, and the impurity layer 190A contains impurities used to form the back surface field regions 140. For example, the impurity layers 190A and 190B may be phosphorous silicate glass (PSG) layers containing phosphorous (P).

On the contrary, when the front surface field region 110 and the back surface field region 140 are of the p-type, the impurity layers 190A and 190B may be borosilicate glass (BSG) layers containing boron (B).

After forming the impurity layers 190A and 190B, the dielectric layer forming step ST50 is performed to form the dielectric layer 150′ on the entire back surface of the substrate 100. In this instance, it is preferable, but not required, that a dielectric layer 120′ is formed on the entire front surface (for example, the entire front surface of the impurity layer 190B) of the substrate 100. It is preferable, but not required, that the dielectric layers 120′ and 150′ are simultaneously formed.

For example, the dielectric layers 120′ and 150′ may contain at least one of oxide, nitride, and oxynitride.

The dielectric layers 120′ and 150′ may be formed at a low temperature of about 200° C. to 500° C. using a chemical vapor deposition (CVD) equipment such as a plasma enhanced CVD (PECVD) equipment, a low pressure CVD (LPCVD) equipment, and an atmospheric pressure CVD (APCVD) equipment, or may be formed at a temperature of a room temperature to about 120° C. through a wet process.

After forming the dielectric layers 120′ and 150′, the thermal process step ST60 is performed.

In the thermal process step ST60, the thermal process is performed on the substrate 100 to diffuse the impurities of the first conductive type contained in the impurity layers 190A and 190B and the impurities of the second conductive type contained in the metal layer 160 into the substrate 100 by a predetermined depth.

In the thermal processing of the substrate 100, the impurities of the first conductive type contained in the impurity layer 190B are diffused into the front surface of the substrate 100 by a predetermined depth to form the front surface field region 110. Further, the impurities of the first conductive type contained in the impurity layer 190A are diffused into the etched portion of the back surface of the substrate 100 by a predetermined depth to form the back surface field regions 140. Further, the impurities of the second conductive type contained in the metal layer 160 are diffused into the back surface of the substrate 100 by a predetermined depth to form the emitter regions 130.

Because the dielectric layers 120′ and 150′ are processed by heat applied during the thermal processing of the substrate 100, the dielectric layer 120′ is formed as the anti-reflection layer 120 and the dielectric layer 150′ is formed as the back passivation layer 150.

As described above, in the method for manufacturing the solar cell according to the embodiment of the invention, an impurity diffusion process for forming the front surface field region 110, the emitter regions 130, and the back surface field regions 140 is performed during the thermal processing of the substrate 100 for forming the anti-reflection layer 120 and the back passivation layer 150.

In other words, the anti-reflection layer 120 and the back passivation layer 150 are formed during the thermal processing of the substrate 100, so as to perform the impurity diffusion process for forming the front surface field region 110, the emitter regions 130, and the back surface field regions 140.

Accordingly, in the embodiment of the invention, because the thermal process is performed once to simultaneously form the front surface field region 110, the anti-reflection layer 120, the emitter regions 130, the back surface field regions 140, and the back passivation layer 150, the number of manufacturing processes of the solar cell may be greatly reduced.

When the front surface field region 110, the anti-reflection layer 120, the emitter regions 130, the back surface field regions 140, and the back passivation layer 150 are simultaneously formed through the above-described steps, the emitter region 130 and the back surface field region 140 may be formed to be separated from each other by the first distance D1 in the vertical direction.

Further, the solar cell may be manufactured so that the first height H1 between the back surface of the front surface field region 110 and the front surface of the back surface field region 140 is less than the second height H2 between the back surface of the front surface field region 110 and the front surface of the emitter region 130, and a difference between the first height H1 and the second height H2 is substantially equal to the first distance D1.

Afterwards, a portion of the back passivation layer 150 and a portion of the impurity layer 190A are removed to form the opening 151 exposing a portion of the metal layer 160 and the opening 152 exposing a portion of the back surface field region 140. The first electrode 170 connected to the back surface field region 140 exposed through the opening 152 and the second electrode 180 connected to the metal layer 160 exposed through the opening 151 are formed. Thus, the solar cell shown in FIGS. 1 and 2 is completed.

When a thermal process temperature of the substrate 100 in the thermal process step ST60 increases to be equal to or higher than about 660° C., aluminum forming the metal layer 160 may be evaporated.

However, in the embodiment of the invention, the dielectric layer 150′ for forming the back passivation layer 150 is formed on the entire back surface of the substrate 100, and then the thermal process step ST60 is performed. Therefore, the dielectric layer 150′ covers the back surface of the metal layer 160 during the thermal process of the substrate 100. Thus, a material forming the metal layer 160 may be prevented from being evaporated during the thermal process of the substrate 100.

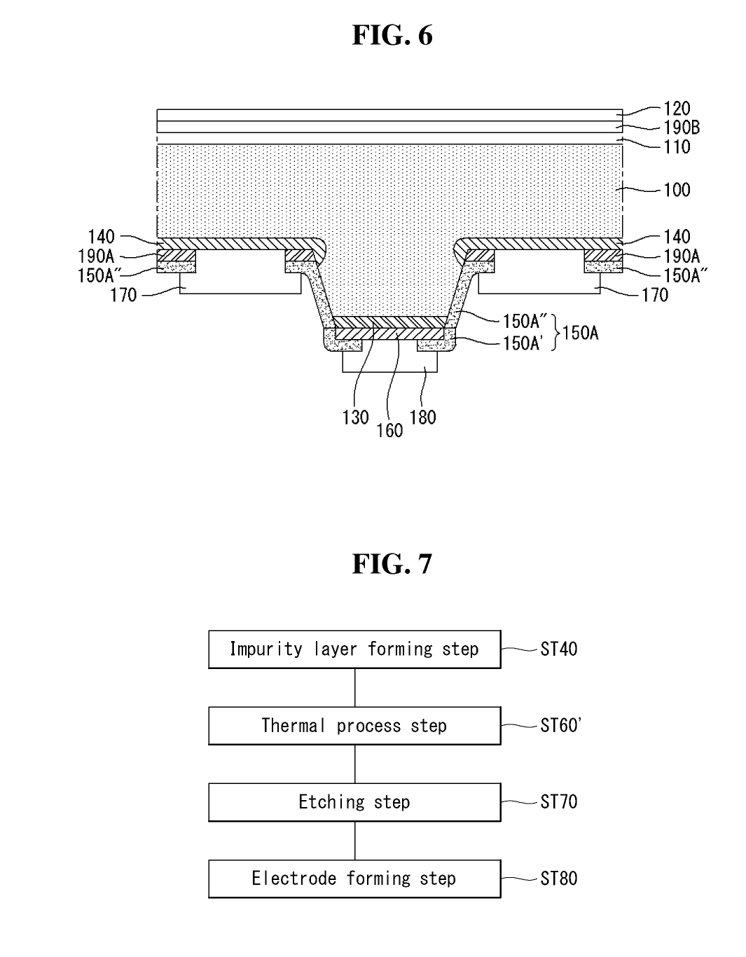

Hereinafter, a solar cell according to a second embodiment of the invention and a method for manufacturing the same are described with reference to FIGS. 6 to 8.

Configuration of the solar cell according to the second embodiment of the invention is substantially the same as the configuration of the solar cell according to the first embodiment of the invention except a back passivation layer 150A.

In the solar cell according to the second embodiment of the invention, the back passivation layer 150A has a single-layered structure and contains two different materials.

More specifically, the back passivation layer 150A includes an aluminum oxide layer 150A′ positioned on a back surface of a metal layer 160 and a silicon oxide layer 150A″ positioned in a remaining area excluding a formation area of the metal layer 160 from a back surface of a substrate 100.

A method for manufacturing the solar cell according to the second embodiment of the invention may include a substrate providing step ST10 for providing the substrate 100 containing impurities of a first conductive type; a metal layer forming step ST20 for forming the metal layer 160 containing impurities of a second conductive type different than the first conductive type on the back surface of the substrate 100 to expose a portion of the back surface of the substrate 100; an etching step ST30 for etching the exposed portion of the back surface of the substrate 100 by a predetermined depth; an impurity layer forming step ST40 for forming an impurity layer 190A containing impurities of the first conductive type at the etched portion of the back surface of the substrate 100; a thermal process step ST60′ for performing a thermal process to form the back passivation layer 150A as a thermal oxide layer on the entire back surface of the substrate 100 and diffusing the impurities of the first conductive type contained in the impurity layer 190A and the impurities of the second conductive type contained in the metal layer 160 into the back surface of the substrate 100 by a predetermined depth to simultaneously form back surface field regions 140 and emitter regions 130; an etching step ST70 for removing a portion of the back passivation layer 150A to expose a portion of each back surface field region 140 and a portion of the metal layer 160; and an electrode forming step ST80 for forming first electrodes 170 connected to the exposed portion of the back surface field regions 140 and second electrodes 180 connected to the exposed portion of the metal layer 160.

Since the method for manufacturing the solar cell according to the second embodiment of the invention is substantially the same as the first embodiment of the invention shown in FIG. 4 except the thermal process step ST60′, a further description may be briefly made.

The method for manufacturing the solar cell according to the second embodiment of the invention does not separately include the dielectric layer forming step ST50 unlike the first embodiment of the invention. The method for manufacturing the solar cell according to the second embodiment of the invention is characterized in that an anti-reflection layer 120 and the back passivation layer 150A formed as the thermal oxide layer are formed in the thermal process step ST60′ for the impurity diffusion.

As described above, in the second embodiment of the invention, after the impurity layer forming step ST40, the dielectric layer forming step ST50 is not performed and the thermal process step ST60′ is performed. Hence, when the thermal process is performed on the substrate 100 at a temperature equal to or higher than about 500° C., the thermal oxide layers are respectively formed on the front surface and the back surface of the substrate 100. The thermal oxide layer formed on the front surface of the substrate 100 serves as the anti-reflection layer 120, and the thermal oxide layer formed on the back surface of the substrate 100 serves as the back passivation layer 150A.

In the method for manufacturing the solar cell according to the second embodiment of the invention, when the thermal process is performed on the substrate 100 at a temperature equal to or higher than about 500° C., the metal oxide layer 150A′ (for example, aluminum oxide layer) is formed on the back surface of the metal layer 160, and the silicon oxide layer 150A″ is formed in the remaining portion.

Accordingly, when the dielectric layer forming step ST50 is omitted and the thermal oxide layer is formed in the thermal process step ST60′ to form the anti-reflection layer 120 and the back passivation layer 150A, the back passivation layer 150A includes the aluminum oxide layer 150A′ and the silicon oxide layer 150A″.

Further, the aluminum oxide layer 150A′ may prevent the metal layer 160 from being evaporated by heat applied to the substrate 100 during the thermal processing of the substrate 100.

As described above, in the second embodiment of the invention, because the dielectric layer forming step ST50 is omitted and the thermal process step ST60′ is performed after the impurity layer forming step ST40, the number of manufacturing processes of the solar cell may be further reduced.

Although embodiments have been described with reference to a number of illustrative embodiments thereof, it should be understood that numerous other modifications and embodiments can be devised by those skilled in the art that will fall within the scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a semiconductor substrate containing impurities of a first conductive type;
a back surface field region on a back surface of the semiconductor substrate and doped more than the semiconductor substrate with impurities of the first conductive type;
an emitter region on the back surface of the semiconductor substrate adjacent to the back surface field region, the emitter region containing impurities of a second conductive type different than the first conductive type;
a metal layer which contains impurities of the second conductive type on a back surface of the emitter region;
a back passivation layer exposing a portion of the back surface field region and a portion of the metal layer;
a first electrode electrically connected to the back surface field region exposed by the back passivation layer; and
a second electrode electrically connected to the metal layer exposed by the back passivation layer.

2. The solar cell of claim 1, further comprising an impurity layer which contains impurities of the first conductive type and is between the back surface field region and the back passivation layer.

3. The solar cell of claim 1, wherein the first electrode directly contacts the back surface field region, and
wherein the second electrode directly contacts the metal layer.

4. The solar cell of claim 1, wherein a width of the emitter region is substantially equal to or greater than a width of the metal layer.

5. The solar cell of claim 1, wherein the semiconductor substrate and the back surface field region are of an n-type, the emitter region is of a p-type, and the metal layer is includes aluminum.

6. The solar cell of claim 5, wherein the back passivation layer includes an aluminum oxide layer on a back surface of the metal layer and a silicon oxide layer in a remaining area excluding a formation area of the metal layer from the back surface of the semiconductor substrate.

7. The solar cell of claim 1, wherein the back passivation layer includes at least one of oxide, nitride, and oxynitride.

8. The solar cell of claim 1, wherein the back surface field region is separated from the emitter region in a vertical direction from the back surface of the semiconductor substrate, or the vertical direction and a horizontal direction.

9. The solar cell of claim 8, further comprising a front surface field region on a front surface of the semiconductor substrate and is doped more than the semiconductor substrate with impurities of the first conductive type.

10. The solar cell of claim 9, wherein a distance between the front surface field region and the emitter region is greater than a distance between the front surface field region and the back surface field region.

11. The solar cell of claim 9, wherein an impurity layer containing impurities of the first conductive type is on a front surface of the front surface field region, and an anti-reflection layer is on an entire front surface of the impurity layer.

12. The solar cell of claim 11, wherein the anti-reflection layer and the back passivation layer include the same material.

13. A method for manufacturing a solar cell comprising:
a metal layer forming step for forming a metal layer containing impurities of a second conductive type different than a first conductive type on a back surface of a semiconductor substrate containing impurities of the first conductive type to expose a portion of the back surface of the semiconductor substrate;
an etching step for etching the exposed portion of the back surface of the semiconductor substrate by a predetermined depth;
an impurity layer forming step for forming an impurity layer containing impurities of the first conductive type on an etched portion of the back surface of the semiconductor substrate;
a dielectric layer forming step for forming a dielectric layer on an back surface of the semiconductor substrate; and
a thermal process step for performing a thermal process to diffuse the impurities of the first conductive type contained in the impurity layer and the impurities of the second conductive type contained in the metal layer into the back surface of the semiconductor substrate by a predetermined depth and simultaneously form a back surface field region and an emitter region.

14. The method of claim 13, wherein during the impurity layer forming step, the impurity layer is further formed on a front surface of the semiconductor substrate,
wherein during the dielectric layer forming step, the dielectric layer is further formed on a front surface of the impurity layer formed on the front surface of the semiconductor substrate.

15. The method of claim 13, wherein during the thermal process step, the impurities of the first conductive type contained in the impurity layer formed on a front surface of the semiconductor substrate are diffused into the front surface of the semiconductor substrate to form a front surface field region,
wherein the thermal process is performed on the dielectric layer formed on a front surface of the front surface field region to form an anti-reflection layer, and
wherein the thermal process is performed on the dielectric layer formed on the back surface of the semiconductor substrate to form a back passivation layer.

16. The method of claim 15, further comprising:
an etching step for removing a portion of the back passivation layer to expose a portion of the back surface field region and a portion of the metal layer; and
an electrode forming step for forming a first electrode connected to the exposed portion of the back surface field region and a second electrode connected to the exposed portion of the metal layer.

17. The method of claim 13, wherein in the metal layer forming step, the metal layer is formed using a deposition method, and
wherein in the etching step, the metal layer is used as a mask.

18. A method for manufacturing a solar cell comprising:
a metal layer forming step for forming a metal layer containing impurities of a second conductive type different than a first conductive type on a back surface of a semiconductor substrate containing impurities of the first conductive type to expose a portion of the back surface of the semiconductor substrate;
an etching step for etching the exposed portion of the back surface of the semiconductor substrate by a predetermined depth;
an impurity layer forming step for forming an impurity layer containing impurities of the first conductive type on the etched portion of the back surface of the semiconductor substrate;
a thermal process step for performing a thermal process to form a back passivation layer as a thermal oxide layer on a back surface of the semiconductor substrate and diffusing the impurities of the first conductive type contained in the impurity layer and the impurities of the second conductive type contained in the metal layer into the back surface of the semiconductor substrate by a predetermined depth to simultaneously form a back surface field region and an emitter region;
an etching step for removing a portion of the back passivation layer to expose a portion of the back surface field region and a portion of the metal layer; and
an electrode forming step for forming a first electrode connected to the exposed portion of the back surface field region and a second electrode connected to the exposed portion of the metal layer.

19. The method of claim 18, wherein in the impurity layer forming step, the impurity layer is further formed on a front surface of the semiconductor substrate,
wherein in the thermal process step, the thermal oxide layer is further formed on a front surface of the impurity layer formed on the front surface of the semiconductor substrate, and the impurities of the first conductive type contained in the impurity layer formed on the front surface of the semiconductor substrate are diffused into the front surface of the semiconductor substrate to form a front surface field region.

20. The method of claim 18, wherein in the metal layer forming step, the metal layer is formed using a deposition method, and
wherein in the etching step, the metal layer is used as a mask.
